(19) United States
(12) Patent Application Publication
(10) Pub. No.: US 2016/0072511 A1
(43) Pub. Date: Mar. 10, 2016

(54) SEMICONDUCTOR DEVICE AND TEST METHOD OF THE SAME

(71) Applicant: KABUSHIKI KAISHA TOSHIBA, Tokyo (JP)

(72) Inventor: Tomoyuki MAEKAWA, Fujisawa Kanagawa (JP)

(21) Appl. No.: 14/636,723

(22) Filed: Mar. 3, 2015

(30) Foreign Application Priority Data
Sep. 9, 2014 (JP) 2014-183383

(51) Int. Cl. H03L 7/085; G01R 31/28

(52) U.S. Cl. CPC H03L 7/085; G01R 31/2882

(57) ABSTRACT

A semiconductor device having a function of detecting abnormality of a frequency of a clock includes a PLL circuit configured to generate a clock signal of the semiconductor device, a delay circuit in which an amount of delay of an output signal with respect to an input signal is equal to an amount of delay at a critical path of the semiconductor device, a first selection circuit configured to select an input to the delay circuit between a first input that is derived from the clock signal and a second input, which is the output signal of the delay circuit, a frequency dividing circuit configured to divide a frequency of the output signal of the delay circuit, and a second selection circuit configured to select as an input to the PLL circuit one of a reference signal and an output of the frequency dividing circuit.

### CROSS-REFERENCE TO RELATED APPLICATION

This application is based upon and claims the benefit of priority from Japanese Patent Application No. 2014-183383, filed Sep. 9, 2014, the entire contents of which are incorporated herein by reference.

### FIELD

Embodiments described herein relate generally to a semiconductor device and a test method of the same.

### BACKGROUND

From a viewpoint of improving reliability or safety of a device, various abnormality detection units are provided in a semiconductor integrated circuit. If abnormality is detected by the abnormality detection units, reset of a semiconductor integrated circuit, or predetermined interrupt is performed, and unintended activation of an integrated circuit is avoided. One example of abnormalities that is a detection target of abnormality detection units is a so-called common cause failure due to a voltage, temperature, or the like. The common cause failure affects an operation of an entire semiconductor integrated circuit. Therefore, an abnormality detection circuit that detects the common cause failure based on a frequency of a clock which defines the operation of a semiconductor integrated circuit is proposed.

An abnormality detection circuit of the related art includes one delay circuit that generates an amount of delay of a semiconductor integrated circuit with the smallest frequency margin, that is, an amount of delay which is equal to an amount of delay at a critical path, and another delay circuit that generates an amount of delay which is equal to an operation margin of an integrated circuit. Then, when an amount of delay of a signal that is output via the two delay circuits is equal to or more than a predetermined value, the abnormality detection circuit predicts that the common cause failure will occur, and resets the semiconductor integrated circuit.

This kind of abnormality detection circuit determines an amount of delay of the delay circuit, in such a manner that the abnormality of a semiconductor integrated circuit may also be detected under any use conditions.

When a semiconductor device is normally operating at the rated frequency, the semiconductor device is tested such that a semiconductor integrated circuit is not erroneously determined to be abnormal. However, when a clock signal of the semiconductor integrated circuit is increased so as to exceed the rated frequency, it is less likely to know in advance (1) whether or not the abnormality detection circuit may detect abnormality, or (2) whether or not the abnormality detection circuit may detect abnormality, before other circuits related to the semiconductor integrated circuit unintentionally activate. For this reason, even if the semiconductor integrated circuit is tested, it is thought that a semiconductor integrated circuit in which an abnormality detection circuit which does not sufficiently detect abnormality is embedded may be released in the market.

In addition, if a test is performed in a wide frequency band, by finely changing a frequency of the clock signal of a semiconductor integrated circuit, the abnormality detection circuit may be correctly tested. However, performing the test in this way requires a certain amount of time. For this reason, it is thought that manufacturing cost of a semiconductor integrated circuit is increased.

### DESCRIPTION OF THE DRAWINGS

FIG. 1 is a block diagram illustrating a semiconductor device according to the present embodiment.

FIG. 2 is a block diagram illustrating an abnormality detection circuit.

FIG. 3 is a diagram illustrating an example of a signal of the semiconductor device.

FIG. 4 is a diagram illustrating a graph representing an amount of delay with respect to PVT conditions.

FIG. 5 is a diagram illustrating a graph representing an amount of delay with respect to PVT conditions.

FIG. 6 is a diagram illustrating a graph representing an amount of delay with respect to PVT conditions.

FIG. 7 is a diagram illustrating a graph representing an amount of delay with respect to PVT conditions.

FIG. 8 is a diagram illustrating a graph representing an amount of delay with respect to PVT conditions.

FIG. 9 is a diagram illustrating a closed circuit (loop circuit) formed in the abnormality detection circuit.

FIG. 10 is a diagram illustrating a modification example of the abnormality detection circuit.

FIG. 11 is a diagram illustrating a modification example of the abnormality detection circuit.

FIG. 12 is a diagram illustrating a graph representing an amount of delay with respect to PVT conditions.

FIG. 13 is a block diagram illustrating an abnormality detection circuit with respect to a modification example.

### DETAILED DESCRIPTION

An exemplary embodiment provides a semiconductor device which correctly tests an abnormality detection function.

In general, according to one embodiment, a semiconductor device having a function of detecting abnormality of a frequency, includes a PLL circuit configured to generate a clock signal of the semiconductor device, a delay circuit in which an amount of delay of an output signal with respect to an input signal is equal to an amount of delay at a critical path of the semiconductor device, a first selection circuit configured to select an input to the delay circuit between a first input that is derived from the clock signal and a second input, which is the output signal of the delay circuit, a frequency dividing circuit configured to divide a frequency of the output signal of the delay circuit, and a second selection circuit configured to select as an input to the PLL circuit one of a reference signal and an output of the frequency dividing circuit.

According to another embodiment, a test method of a semiconductor device having a function of detecting abnormality of a frequency, includes the steps of generating a first input signal based on a clock signal generated by a PLL circuit for the semiconductor device, delaying an output signal of a delay circuit with respect to an input signal by an amount that is equal to an amount of delay at a critical path of the semiconductor device, selecting as an input to the delay circuit one of the first input signal and a second input signal, which is the output signal of the delay circuit, dividing a frequency of the output signal of the delay circuit to produce a divided frequency signal, and selecting as an input to the PLL circuit one of a reference signal and the divided frequency signal.

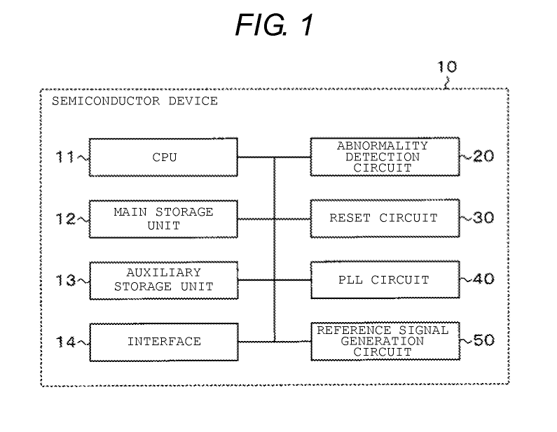

Hereinafter, exemplary embodiments will be described using the drawings. FIG. 1 is a block diagram of a semiconductor device 10 according to the present embodiment. The semiconductor device 10 is a micro controller that includes a central processing unit (CPU) 11, a main storage unit 12, an auxiliary storage unit 13, an interface 14, an abnormality detection circuit 20, a reset circuit 30, a phase locked loop (PLL) circuit 40, and a reference signal generation circuit 50.

The CPU 11 performs arithmetic processing according to a program stored in the auxiliary storage unit 13. A signal indicating an arithmetic result is output to an external unit via the interface 14.

The main storage unit 12 includes a volatile memory such as a random access memory (RAM). The main storage unit 12 is used as a work area of the CPU 11. The auxiliary storage unit 13 includes a non-volatile memory such as a read only memory (ROM). The auxiliary storage unit 13 stores a program that is executed by the CPU 11, various parameters, and the like.

The interface 14 is configured with terminals for connecting the semiconductor device 10 to an external circuit. A circuit that is formed on a substrate on which the semiconductor device 10 is mounted is connected to the semiconductor device 10 via the interface 14. In addition, when the semiconductor device 10 is tested, a test circuit is connected to the semiconductor device 10 via the interface 14.

The abnormality detection circuit 20 includes a circuit that generates an amount of delay that is obtained by adding an amount of delay of a circuit (critical path) having a high possibility of a common cause failure to an amount of delay corresponding to a constant margin. The reason for considering a constant margin is to increase an amount of delay of the abnormality detection circuit 20 for detecting abnormality in a conservative manner.

In the semiconductor device 10, the CPU 11 has the largest amount of delay. For this reason, the abnormality detection circuit 20 includes a circuit that generates an amount of delay that is obtained by adding an amount of delay which is equal to that of a circuit configuring the CPU 11 to an amount of delay corresponding to a constant margin.

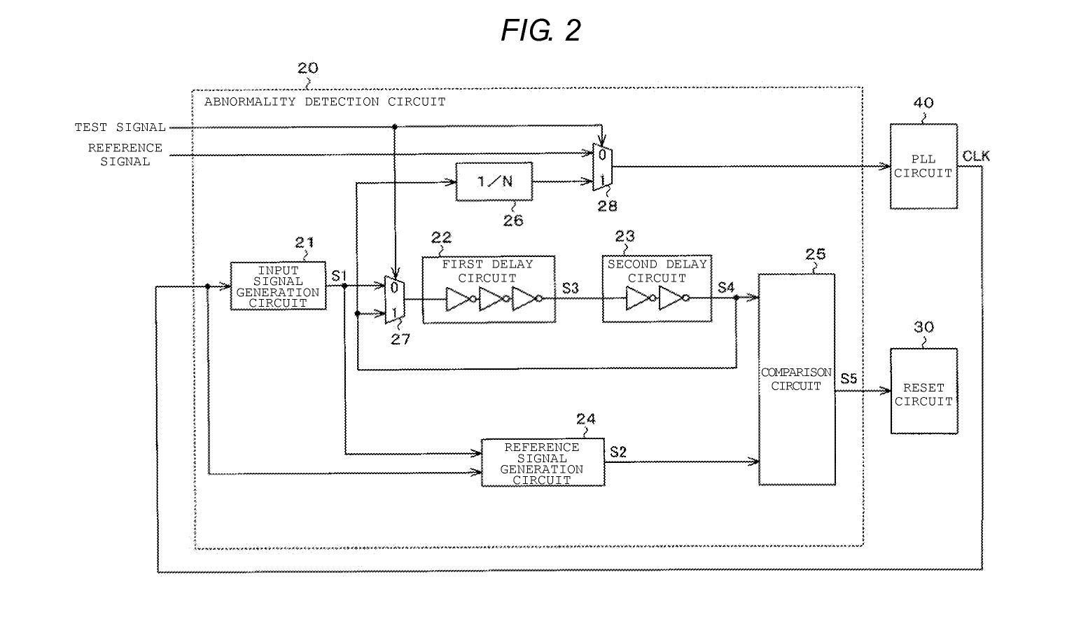

FIG. 2 is a block diagram of the abnormality detection circuit 20. The abnormality detection circuit 20 in FIG. 2 includes an input signal generation circuit 21, a first delay circuit 22, a second delay circuit 23, a reference signal generation circuit 24, a comparison circuit 25, a frequency divider 26, and multiplexers 27 and 28.

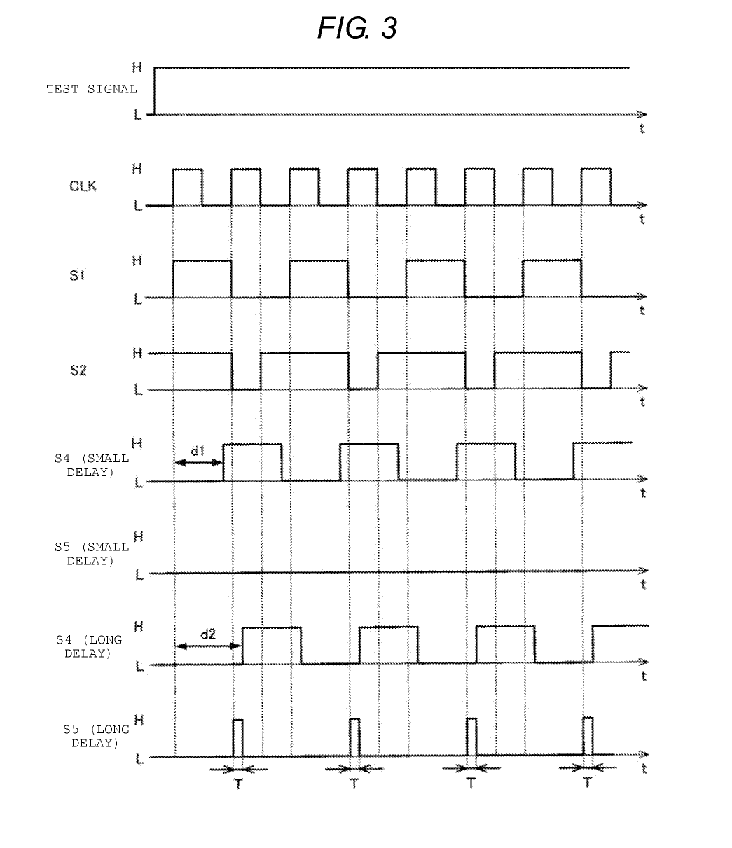

The input signal generation circuit 21 generates a signal S1 based on a clock signal CLK that is output from the PLL circuit 40. FIG. 3 is a diagram illustrating an example of a signal of the semiconductor device 10 according to the present embodiment. The clock signal CLK periodically becomes a low level and a high level, and is a signal of, for example, approximately 200 MHz. The input signal generation circuit 21 generates the signal S1 of, for example, 100 MHz by frequency-dividing the clock signal CLK, and outputs the signal S1 to the multiplexer 27 and the reference signal generation circuit 24.

The multiplexer 27 selects one of two signals that are input, based on a test signal, and outputs the selected signal to the first delay circuit 22. The multiplexer 27 receives the signal S1 that is output from the input signal generation circuit 21 and a delay signal S4 that is output from the second delay circuit 23. The multiplexer 27 outputs the signal S1 to the first delay circuit 22 when the test signal is a low level, and outputs the delay signal S4 to the first delay circuit 22 when the test signal is a high level.

The first delay circuit 22 is a circuit that is configured with, for example, an odd number of NOT gates. The NOT gate may use inverters. The number of inverters is determined according to an amount of delay of the CPU 11, for example. An amount of delay with respect to the input of the first delay circuit 22 is equal to an amount of delay at CPU 11.

The second delay circuit 23 is a circuit that is configured with, for example, an even number of NOT gates. The NOT gate uses inverters. The number of inverters is determined in such a manner that a value which is obtained by adding an amount of delay of the first delay circuit 22 to an amount of delay of the second delay circuit 23 is greater than an amount of delay of the CPU 11 by the constant margin.

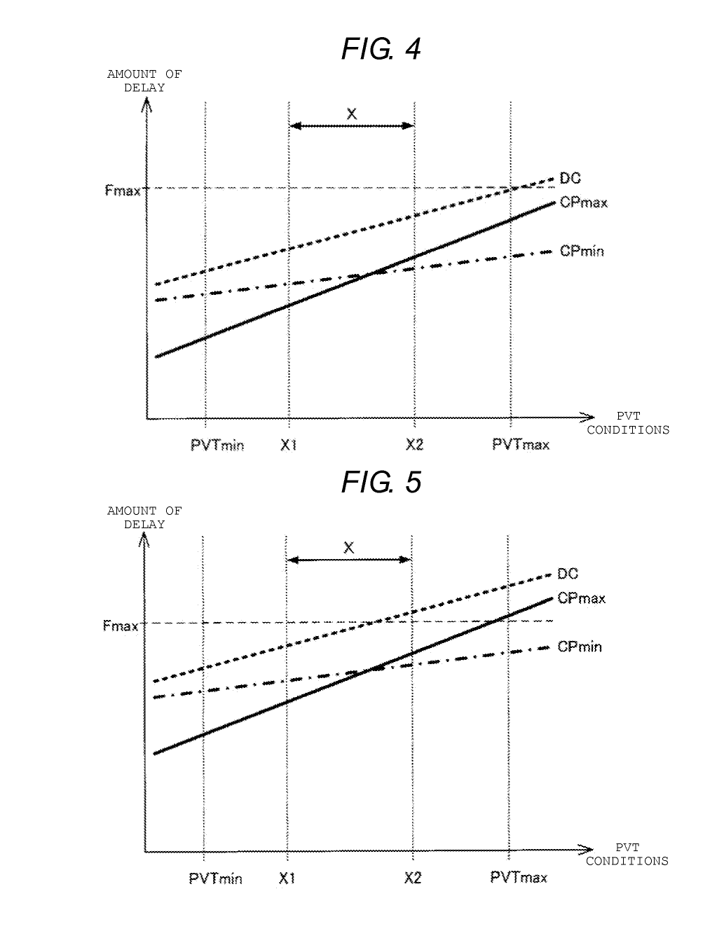

FIGS. 4 to 8 are diagrams illustrating graphs representing an amount of delay with respect to PVT conditions. The PVT conditions are conditions that are determined by three causes of process variation (P), an application voltage (V) of the semiconductor device 10, and temperature (T) of the semiconductor device 10. Linear lines CPmax in FIGS. 4 to 8 illustrate changes in the amount of delay of the semiconductor device 10 when the three causes of the PVT conditions is maximized at a range X. Linear lines CPmin in FIGS. 4 to 8 illustrate changes in the amount of delay of the semiconductor device 10 when the three causes of the PVT conditions is minimized at the range X. In addition, linear lines DC represent changes in the amount of delay generated in the abnormality detection circuit.

The graph of FIG. 4 illustrates an amount of delay when the semiconductor device 10 exhibits initial (non-deteriorated) performance, together with an amount of delay of the abnormality detection circuit. As illustrated in FIG. 4, an amount of delay of the CPU 11 may be divided into approximately two cases: one case where the amount of delay of the CPU 11 is changed so as to be represented by the linear line CPmax with respect to the PVT conditions; and the other case where the amount of delay of the CPU 11 is changed so as to be represented by the linear line CPmin. In addition, in the present embodiment, an amount of delay D that is obtained by adding an amount of delay of the first delay circuit 22 to an amount of delay of the second delay circuit 23 is usually greater than an amount of delay of the CPU 11, in the range X, so as to be represented by the linear line DC in FIG. 4.

A reference value Fmax is a maximum amount of delay that is allowed when the CPU 11 operates without the common cause failure of the semiconductor device 10. During the operation of the semiconductor device 10, the amount of delay D at the abnormality detection circuit 20 is monitored, and when the amount of delay D is equal to or more than the reference value Fmax, the semiconductor device 10 is reset. That is, before the amount of delay at the CPU 11 exceeds the reference value Fmax, the semiconductor device 10 is reset, whereby it is possible to avoid an occurrence of the common cause failure due to a delay of the CPU 11.

The graph of FIG. 5 illustrates an amount of delay when the semiconductor device 10 is deteriorated over time, together with the amount of delay of the abnormality detection circuit. For example, when an amount of delay of each circuit of the semiconductor device 10 is increased because of deterioration over time, the linear line DC is intersected with a line indicating the reference value Fmax, even when the PVT conditions are within the range X, as illustrated in FIG. 5. This means that the amount of delay D which is obtained by adding each amount of delay of the first delay circuit 22 and the second delay circuit 23 to each other exceeds the reference value Fmax.

In the present embodiment, the linear line DC is positioned over the linear line CPmax and the linear line CPmin, in the range X. For this reason, if the semiconductor device 10 is reset when the amount of delay D becomes equal to or more than the reference value Fmax, it is possible to avoid situations where the amount of delay at the CPU 11 becomes equal to or more than the reference value Fmax, and to prevent the common cause failure from occurring.

The signal S1 that is output from the input signal generation circuit 21 is input to the second delay circuit 23 via the first delay circuit 22. Then, the signal is output to the comparison circuit 25 and the frequency divider 26, as the delay signal S4 that is obtained by delaying the signal S1 by a predetermined amount of delay. In the example illustrated in FIG. 3, the delay signal S4 is delayed by time d1 or d2 with respect to the signal S1.

The reference signal generation circuit 24 generates a reference signal S2 based on the signal S1, and outputs the reference signal S2 to the comparison circuit 25 by synchronizing with the clock signal CLK. Specifically, as illustrated in FIG. 3, the reference signal generation circuit 24 generates a reference signal S2 that falls in synchronization with a falling edge of the signal S1 and rises in synchronization with a falling edge of the clock signal CLK, and outputs the reference signal S2 to the comparison circuit 25.

The comparison circuit 25 compares the reference signal S2 with the delay signal S4, and outputs a comparison signal S5 indicating a comparison result. Specifically, the comparison circuit 25 outputs the comparison signal S5 that becomes a high level when the reference signal S2 and the delay signal S4 both are low levels, and in the other cases, for example, when at least one of the reference signal S2 and the delay signal S4 is a high level, the comparison circuit 25 outputs the comparison signal S5 that becomes a low level. As illustrated in FIG. 3, the comparison signal S5 becomes a high level, when an amount of delay of the delay signal S4 is increased, that is, when the delay signal S4 is delayed by one period or more of the clock signal CLK. In addition, the time that the comparison signal S5 is maintained as a high level indicates an amount of delay of the delay signal S4. Meanwhile, when the amount of delay of the delay signal S4 is decreased, that is, when the delay signal S4 is not delayed by one period or more of the clock signal CLK, the comparison signal S5 is maintained as a low level.

Time T in which the comparison signal S5 is maintained as a high level becomes longer, because the amount of delay of the delay signal S4 is increased during the time T. Thus, by monitoring the time T when the comparison signal S5 is a high level, it is possible to predict an occurrence of the common cause failure due to the delay of the CPU 11.

The frequency divider 26 divides a frequency of the delay signal S4, and outputs the signal to the multiplexer 28. The frequency of the delay signal S4 is 100 MHz in the same manner as the frequency of the signal S1. The frequency divider 26 divides the frequency of the delay signal S4 into, for example, 10 MHz, and outputs the signal to the multiplexer 28.

The multiplexer 28 selects one of two signals that are input, based on the test signal, and outputs the signal to the PLL circuit 40. The multiplexer 28 receives the frequency-divided delay signal S4 and the reference signal that is output from the reference signal generation circuit 50. The multiplexer 28 outputs the reference signal to the PLL circuit 40 when the test signal is a low level, and outputs the frequency-divided delay signal S4 to the PLL circuit 40 when the test signal is a high level.

The reference signal generation circuit 50 illustrated in FIG. 1 is an oscillation circuit that uses, for example, crystal as a tuning circuit. The reference signal generation circuit 50 generates a reference signal that periodically becomes a high level and a low level at a frequency of, for example, 10 MHz, and outputs the reference signal.

The reset circuit 30 receives the comparison signal S5 that is output from the comparison circuit 25. Then, the time T (refer to FIG. 3) that the comparison signal S5 is maintained as a high level is measured. If the time T exceeds a threshold, the reset circuit 30 resets the operation of the semiconductor device 10. As a result, the semiconductor device 10 is initialized, and an occurrence of the common cause failure due to an increase of the amount of delay at the CPU 11 is avoided.

The PLL circuit 40 includes a phase comparator, a voltage controlled oscillator (VCO), a low pass filter, and a frequency divider, and functions as a synthesizer that multiplies an input signal. When the reference signal or the delay signal S4 is input, the PLL circuit 40 generates the clock signal CLK of, for example, approximately 200 MHz that is obtained by multiplying a frequency of the reference signal. Then, the PLL circuit 40 outputs the generated clock signal CLK to the CPU 11, the input signal generation circuit 21, the reference signal generation circuit 24, and the like.

The CPU 11 controls the main storage unit 12, the auxiliary storage unit 13, and the like, in synchronization with the clock signal CLK. In addition, the abnormality detection circuit 20 detects abnormality, based on the delay signal S4.

Next, a sequence of performing the test of the semiconductor device 10 will be described. When the semiconductor device 10 is tested, a test device is connected to the semiconductor device 10 via the interface 14.

The test device is a circuit for determining whether or not an operation of each unit that configures the semiconductor device 10 is normal. The test device tests the semiconductor device 10, by selectively switching outputs of the multiplexers 27 and 28, based on the test signal.

As illustrated in FIG. 4, the test device first performs a first test by operating the semiconductor device 10 at a condition where the PVT conditions are within the range X. The first test is a test for detecting the abnormality of the semiconductor device 10.

When there is no abnormality in the semiconductor device 10, the amount of delay D at the first delay circuit 22 and the second delay circuit 23 becomes an amount equal to or less than the reference value Fmax, as represented by the linear line DC. The amount of delay D is designed so as to be increased more than the amount of delay at the CPU 11 that is represented by the linear line CPmax and the linear line CPmin, and thus, when the PVT conditions are within the range X, if the comparison signal S5 does not become a high level, the semiconductor device 10 may be considered to operate normally.

In this case, even though the semiconductor device 10 is deteriorated over time, the amount of delay D that is considered to be the largest at this moment exceeds the reference value Fmax at the first time. Thus, by monitoring the amount of delay D, it is possible to predict an occurrence of the common cause failure due to the delay at other circuits.

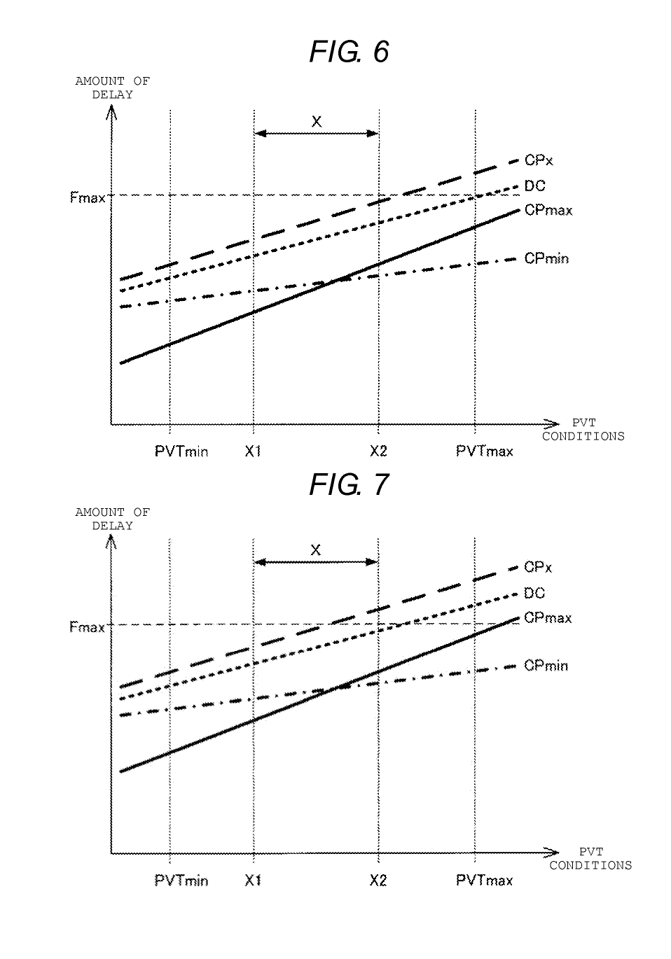

The graph of FIG. 6 illustrates an amount of delay in a case where the semiconductor device 10 includes a circuit (hereinafter, also referred to as a specific circuit C) having an amount of delay more than the amount of delay of the first and second delay circuits 22, 23, together with the amount of delay of the abnormality detection circuit. In addition, the graph of FIG. 7 illustrates an amount of delay when the semiconductor device 10 including the specific circuit C is deteriorated over time, together with the amount of delay of the abnormality detection circuit. In addition, linear lines CPx in FIG. 6 and FIG. 7 illustrate changes in the amount of delay of the specific circuit C.

As illustrated in FIG. 6, the semiconductor device 10 includes the specific circuit C in which an amount of delay in the range X changes, for example, as represented by the linear line CPx. In this case, when the PVT conditions are within the range X, the amount of delay of the specific circuit C is increased more than the amount of delay D of the abnormality detection circuit 20.

For this reason, when the circuit characteristics deteriorate over time and the amount of delay of the specific circuit C exceeds the reference value Fmax prior to the amount of delay D of the abnormality detection circuit 20, as illustrated in FIG. 7, the semiconductor device 10 will operate normally when the PVT conditions are within the range X, because the abnormality is not detected by the abnormality detection circuit 20 is used. In such case, a control for resetting the semiconductor device 10 is performed only when the amount of delay D becomes equal to or more than the reference value Fmax, and, as a result, the common cause failure occurs due to the specific circuit C.

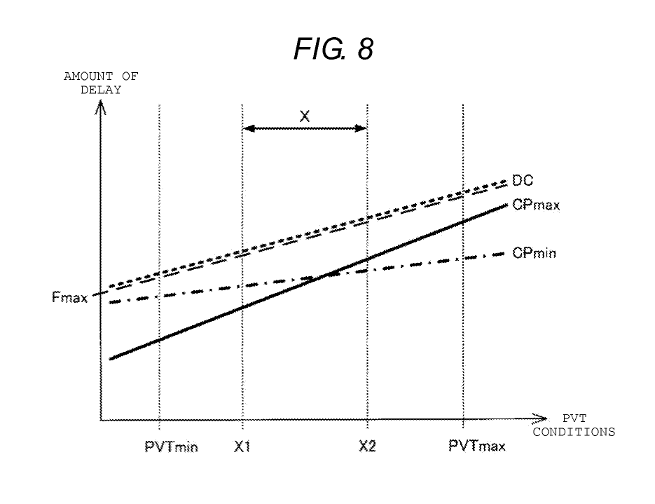

Therefore, in the present embodiment, as illustrated by a broken line in FIG. 8, the reference value Fmax is defined to correspond to the linear line DC, and a second test is performed. The second test is a test for detecting whether or not the specific circuit C having an amount of delay which exceeds the reference value Fmax is included in the semiconductor device 10.

The graph of FIG. 8 illustrates delay characteristics of the reference value Fmax at the time of the second test. In FIG. 8, the reference value Fmax is defined to be slightly less than the amount of delay D represented by the linear line DC. For this reason, as represented by the linear lines CPx of FIG. 6 and FIG. 7, even when there exists the specific circuit C having an amount of delay more than the amount of delay D of the abnormality detection circuit 20 that is represented by the linear line DC within the range X, it is possible to detect an abnormality caused by the specific circuit C by performing the second test. In such a case, the semiconductor device 10 which includes the specific circuit C is treated as a defective product without resetting the semiconductor device 10.

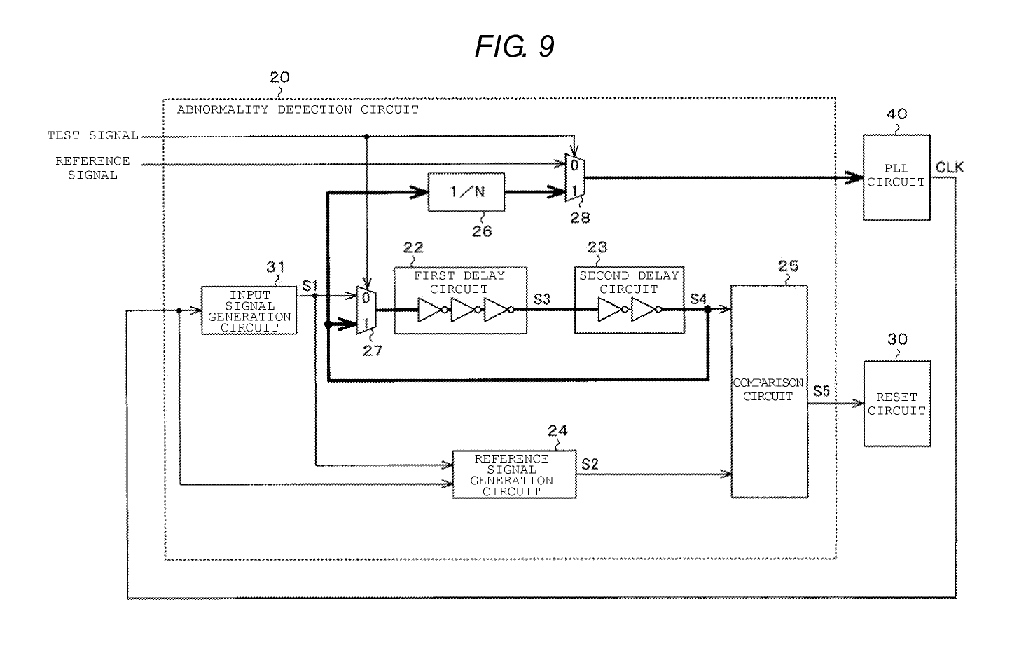

In the second test, the test device sets the test signal to a high level. As a result, as illustrated in FIG. 9, a closed circuit by which the delay signal S4 is fed back to the first delay circuit 22, and a circuit that inputs the delay signal S4 to the PLL circuit via the frequency divider 26 are formed.

The first delay circuit 22 includes an odd number of inverters, and the second delay circuit 23 includes an even number of inverters. For this reason, if the test signal becomes a high level, the first delay circuit 22 and the second delay circuit 23 form a ring oscillator. An oscillation frequency of the ring oscillator depends upon a total number of inverters and delay time of each inverter. In the present embodiment, the ring oscillator with a frequency of, for example, approximately 250 MHz is formed. Thus, when the second test is performed, the delay signal S4 becomes a binary signal of approximately 250 MHz.

The delay signal S4 becomes a unique frequency of the ring oscillator. Thus, the abnormality detection circuit 20 may perform the test of the semiconductor device 10 using the unique frequency.

The delay signal S4 that is generated by the first delay circuit 22 and the second delay circuit 23 which become the ring oscillator is input to the comparison circuit 25. At this time, as represented by the linear line CPx of FIG. 6, the amount of delay of a circuit that makes the common cause failure occur increases more than the amount of delay D that is represented by the linear line DC. Therefore, if the common cause failure occurs, it is determined that the specific circuit C exists in the semiconductor device 10, and the semiconductor device 10 is treated as a defective product.

As described above, in the present embodiment, when the semiconductor device 10 is tested, the first delay circuit 22 and the second delay circuit 23 become a ring oscillator. As a result, the delay signal S4 becomes the unique frequency of the ring oscillator. Thus, it is possible to test the operation of the semiconductor device 10, by using as a reference an actual frequency of a delay circuit that is configured with the first delay circuit 22 and the second delay circuit 23. It is determined that the specific circuit C exists in the semiconductor device 10 in the test. Then, it is determined that the function of the abnormality detection circuit 20 which predicts an occurrence of the common cause failure is not sufficient. Therefore, the semiconductor device 10 having the abnormality detection circuit 20 whose function is not sufficient is handled as a defective product, and thus it is possible to provide only a semiconductor device with a high reliability.

In addition, it is possible to test the function of the abnormality detection circuit 20, without testing at a wide frequency band, by finely changing the frequency of the clock signal of the semiconductor device 10. Therefore, it is possible to perform the test in a short time, and to reduce the manufacturing cost of the semiconductor device.

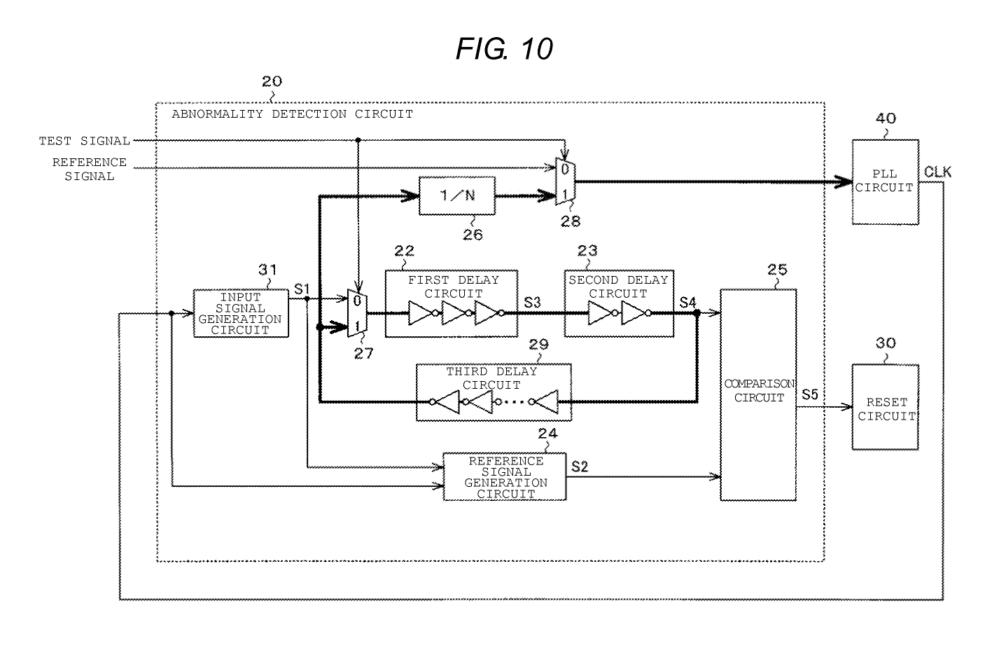

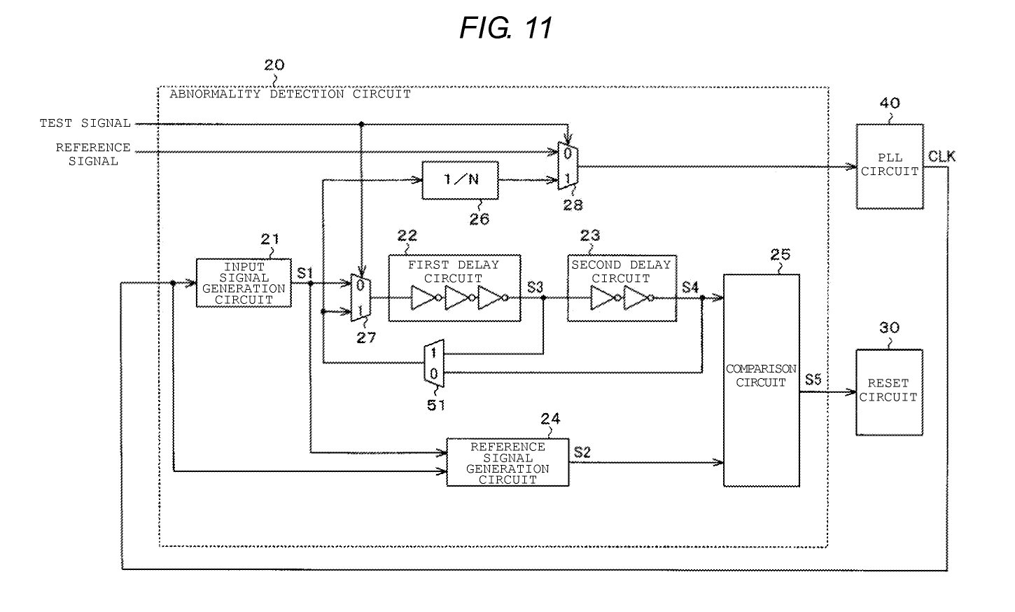

Exemplary embodiments are described above; however, the exemplary embodiments and disclosure are not limited to the above-described embodiments. For example, in the above-described embodiments, as illustrated in FIG. 9, the ring oscillator that is formed by the first delay circuit 22 and the second delay circuit 23 is described. While not being limited to this, the ring oscillator may be formed by the first delay circuit 22, the second delay circuit 23, and a third delay circuit 29 configured with inverters, as illustrated in FIG. 10.

For example, when a difference between the amount of delay D for detecting abnormality and the amount of delay of the specific circuit C is small, the common cause failure may occur by mistake during testing, under the influence of the clock jitter or the like of the PLL circuit 40. For this reason, it is possible to complement the influence of the clock jitter by decreasing the frequency of the delay signal S4 using the third delay circuit 29. As a result, it is possible to correctly test the semiconductor device 10.

In the above-described embodiments, a case where the ring oscillator is formed by the first delay circuit 22 and the second delay circuit 23 is described. While not being limited to this, a multiplexer 51 is provided, and instead of the delay signal S4, the signal S3 output from the first delay circuit 22 may be output to the first delay circuit 22 and the frequency divider 26, as illustrated in FIG. 11. In this case, the ring oscillator is formed by the first delay circuit 22.

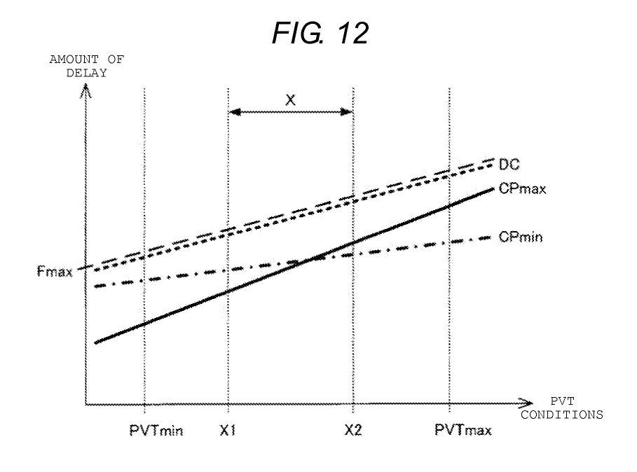

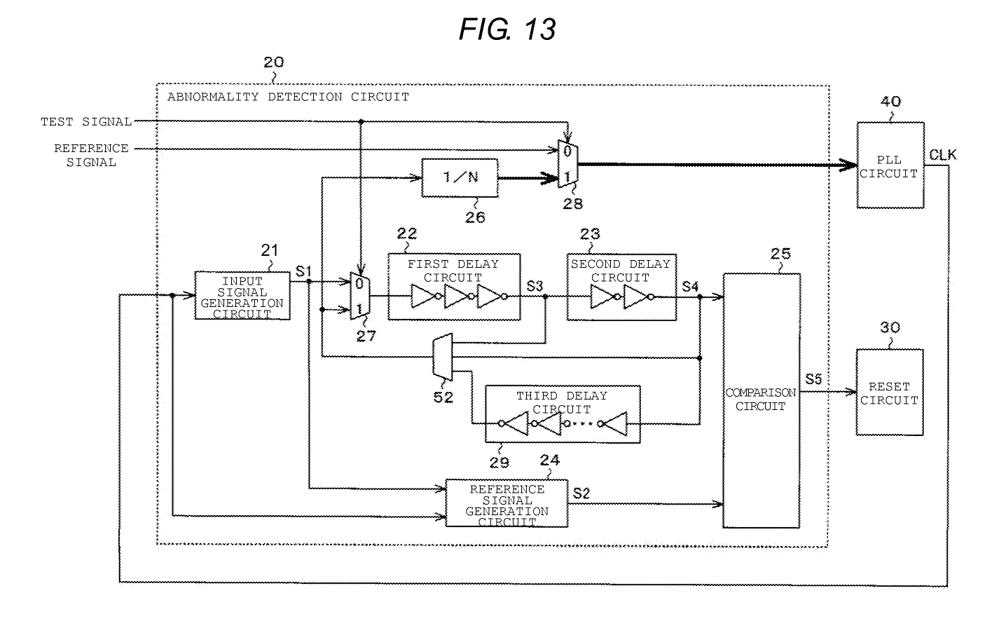

FIG. 12 is a graph illustrating delay characteristics of the reference value Fmax at the time of the second test of the semiconductor device 10 including the abnormality detection circuit 20 of FIG. 11. When the ring oscillator is formed by the first delay circuit 22 only, the reference value Fmax becomes slightly larger than the amount of delay D represented by the linear line DC, as illustrated in FIG. 12. For this reason, as represented by the linear line CPx of FIG. 6 and FIG. 7, even when there exists the specific circuit C having an amount of delay more than the amount of delay D of the abnormality detection circuit 20 that is represented by the linear line DC within the range X, it is possible to detect the specific circuit C by performing the second test. In this case, by making the amount of delay of the first delay circuit 22 slightly less than the amount of delay of the specific circuit C, it is possible to test whether or not the delay caused by the specific circuit C may be detected.

In addition, in the abnormality detection circuit 20 of FIG. 11, by operating the multiplexer 51, a signal that is input to the first delay circuit 22 may be switched. Thus, by a single test, the abnormality detection circuit 20 may detect the abnormality, and it is possible to test the presence or absence of the specific circuit C that causes the common cause failure which cannot be detected by the abnormality detection circuit 20.

In addition, as illustrated in FIG. 13, a signal that is input to the first delay circuit 22 may be selected by a selection unit 52, from among the output signals of the first delay circuit 22, the second delay circuit 23, and the third delay circuit 29.

In the abnormality detection circuit 20 illustrated in FIG. 11 and FIG. 13, the number of the NOT gates by which the ring oscillator is formed is changed, and thus it is possible to perform a test with regard to various cases.

In the above-described embodiments, a case where the delay circuit is configured with inverters is described. The configuration of the delay circuit is not limited to this, and other oscillation circuits may be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device having a function of detecting abnormality of a frequency, comprising:
a PLL circuit configured to generate a clock signal of the semiconductor device;
a delay circuit in which an amount of delay of an output signal with respect to an input signal is equal to an amount of delay at a critical path of the semiconductor device;
a first selection circuit configured to select an input to the delay circuit between a first input that is derived from the clock signal and a second input, which is the output signal of the delay circuit;
a frequency dividing circuit configured to divide a frequency of the output signal of the delay circuit; and
a second selection circuit configured to select as an input to the PLL circuit one of a reference signal and an output of the frequency dividing circuit.

2. The device according to claim 1,
wherein the delay circuit includes a first delay circuit having an amount of delay that is equal to the amount of delay at the critical path.

3. The device according to claim 2,
wherein the delay circuit includes a second delay circuit having an amount of delay that is equal to a variation range of the amount of delay at the critical path.

4. The device according to claim 3,
wherein the delay circuit includes a third delay circuit connected in series with the first and second delay circuits.

5. The device according to claim 4, further comprising:
a third selection unit configured to select the output of the delay circuit as one of the outputs of the first, second, and third delay circuits.

6. The device according to claim 1, further comprising:
an input signal generation circuit configured to generate the first input from the clock signal.

7. The device according to claim 1, further comprising:
a comparison circuit configured to detect a presence of an abnormality in the semiconductor device based on the output of the delay circuit.

8. The device according to claim 7, further comprising:
a reset circuit configured to reset the semiconductor device when the comparison circuit detects an abnormality in the semiconductor device.

9. An abnormality detection circuit for a semiconductor device, comprising:
an input signal generation circuit configured to generate a first input signal based on a clock signal generated by a PLL circuit for the semiconductor device;
a delay circuit in which an amount of delay of an output signal with respect to an input signal is equal to an amount of delay at a critical path of the semiconductor device;
a first selection circuit configured to select as an input to the delay circuit one of the first input signal and a second input signal, which is the output signal of the delay circuit;
a frequency dividing circuit configured to divide a frequency of the output signal of the delay circuit; and
a second selection circuit configured to select as an input to the PLL circuit one of a reference signal and an output of the frequency dividing circuit.

10. The circuit according to claim 9,
wherein the delay circuit includes a first delay circuit having an amount of delay that is equal to the amount of delay at the critical path.

11. The circuit according to claim 10,
wherein the delay circuit includes a second delay circuit having an amount of delay that is equal to a variation range of the amount of delay at the critical path.

12. The circuit according to claim 11,
wherein the delay circuit includes a third delay circuit connected in series with the first and second delay circuits.

13. The circuit according to claim 12, further comprising:
a third selection unit configured to select the output of the delay circuit as one of the outputs of the first, second, and third delay circuits.

14. The device according to claim 9, further comprising:
a comparison circuit configured to detect a presence of an abnormality in the semiconductor device based on the output of the delay circuit and supply a reset signal to a reset circuit configured to reset the semiconductor device when the comparison circuit detects an abnormality in the semiconductor device.

15. A test method of a semiconductor device having a function of detecting abnormality of a frequency, the method comprising:
generating a first input signal based on a clock signal generated by a PLL circuit for the semiconductor device;
delaying an output signal of a delay circuit with respect to an input signal by an amount that is equal to an amount of delay at a critical path of the semiconductor device;
selecting as an input to the delay circuit one of the first input signal and a second input signal, which is the output signal of the delay circuit;
dividing a frequency of the output signal of the delay circuit to produce a divided frequency signal; and
selecting as an input to the PLL circuit one of a reference signal and the divided frequency signal.

16. The method according to claim 15,
wherein the delay circuit includes a first delay circuit having an amount of delay that is equal to the amount of delay at the critical path.

17. The method according to claim 16,
wherein the delay circuit includes a second delay circuit having an amount of delay that is equal to a variation range of the amount of delay at the critical path.

18. The method according to claim 17,
wherein the delay circuit includes a third delay circuit connected in series with the first and second delay circuits.

19. The method according to claim 18, further comprising:
selecting the output of the delay circuit as one of the outputs of the first, second, and third delay circuits.

20. The method according to claim 15, further comprising:
detecting a presence of an abnormality in the semiconductor device based on the output of the delay circuit; and
supplying a reset signal to a reset circuit configured to reset the semiconductor device when the abnormality in the semiconductor device is detected.
